(19) United States
(12) Patent Application Publication
(10) Pub. No.: US 2006/0114955 A1
(43) Pub. Date: Jun. 1, 2006

(54) Spectral control of laser diode bars and stacks

(76) Inventor: Gregory J. Steckman, San Gabriel, CA (US)

Correspondence Address: ONDAX, INC., 850 EAST DUARTE ROAD, MONROVIA, CA, 91016, US

(21) Appl. No.: 11/282,855

(22) Filed: Nov. 17, 2005

Related U.S. Application Data
(60) Provisional application No. 60/628,766, filed on Nov. 17, 2004.
(60) Provisional application No. 60/670,913, filed on Apr. 12, 2005.

(51) Int. Cl. H01S 5/00; H01S 3/08

(52) U.S. Cl. 372/50.12; 372/98

(57) ABSTRACT

The present invention provides controlling the locked wavelength of individual diodes in an array such that the spectral output of the array when taken as a whole is of the desired form for a given application. In one embodiment, a volume holographic grating is formed that has a wavelength that varies on the filter in accordance with the physical position of a laser emitter in a diode bar or stack. The system can be used in connection with a collimator disposed to receive the output of a diode bar or stack of diode bars. The modified filter is then disposed adjacent the output of the collimator to provide a suitable shaped spectral output. This technique can be applied to stacks of laser diode bars, where each bar can be made to operate at any desired wavelength, or even individual emitters within the bar, such that the combined spectral output is designed for a particular application.

This patent application claims the benefit of priority of pending provisional patent application 60/628,766 filed Nov. 17, 2004 entitled “Spectral Control of Laser Diode Bars and Stacks” and pending provisional patent application 60/670,913 entitled “Method and Apparatus for Wafer Fabrication of Volume Holographic Reflection” filed Apr. 12, 2005, both of which are incorporated by reference herein in their entirety.

### BACKGROUND OF THE INVENTION

1. Field of the Invention

This invention relates to the field of laser diodes.

2. Background

Some types of laser diodes come in the form of diode arrays, referred to as bars. They typically consist of 10 to 20 emitters disposed adjacent to one another. However, the exact number, dimensions, and spacing of diode arrays and bars may vary. Typically the output of the laser bar is coupled into a single optical fiber. The spectrum measured at the output of the fiber is the sum of the spectra of the individual laser diodes.

The laser diodes on a single bar are designed to be identical, but due to manufacturing and environmental variations they may not all operate at the same wavelength and with the same spectral shape. See for example U.S. Pat. No. 5,691,989. A single volume holographic grating has been used and shown to be effective at stabilizing and locking the wavelengths of a diode bar so that the cumulative spectrum is narrowed. The grating pulls the wavelength of each diode to match the center wavelength of the grating. Consequently, all diodes of the bar operate at the same wavelength and when combined into a fiber the spectrum is narrower than that of a free-running bar. FIGS. 1A and 1B illustrate an unstabilized (FIG. 1A) laser diode bar and a laser diode bar stabilized (FIG. 1B) with a volume holographic grating.

Referring first to FIG. 1A, the diode bar 100 includes a plurality of emitters 101A-101N that provide output beams 102A-102N to collimator 103. The output of collimator 103 is output beams 105A-104N. The matching of the output beams 105A-104N is dependent on the matching of the diodes of the diode bar 100, which, as noted above, may be affected by manufacturing and environment.

FIG. 1B is one prior art solution for providing more consistent output. As before, the diode bar 100 includes a plurality of emitters 101A-101N that provide output beams 102A-102N to collimator 103. Here a volume holographic grating 105 is disposed adjacent the collimator 103. The grating 105 pulls the wavelength of each beam 102A-102N to the center wavelength of the grating 105. Output beams 107A-106N are then matched to the center wavelength of the grating 105.

Multiple laser diode bars can be stacked one atop another to form what is called a stack. Typically the outputs of all emitters from all bars are coupled into a single optical fiber. In this configuration a volume holographic grating can also be used for each bar in the stack or a single element covering all bars, thereby narrowing the spectrum of the combined lasers. FIGS. 2A and 2B illustrate an un-stabilized stack (FIG. 2A) and a stabilized stack (FIG. 2B).

Referring to FIG. 2A, a stack of diode bars 200A-200N, each having a plurality of emitters, produces output beams 202A-202N to collimator stack 203A-203N. The collimator stack has output beams 205A-204N. As noted with a single diode bar, the output beams have a wavelength that depends on the wavelengths of the laser diodes and may be inconsistent.

FIG. 2B illustrates a similar setup with a volume holographic grating provided to match wavelengths. As in FIG. 2A, a stack of diode bars 200A-200N, each having a plurality of emitters, produces output beams 202A-202N to collimator stack 203A-203N. A volume holographic grating 205 is disposed adjacent to the collimator stack 203A-203N. The output beams 207A-206N are then matched to the center frequency of the grating 205.

A characteristic of the systems of FIGS. 1 and 2 is that they provide a specific spectral output. The combination of multiple lasers having the same spectral output results in the same spectral output with an increase in total power output. An example of the spectral output of a single laser diode is illustrated in FIG. 3. By way of example, the laser has a center wavelength of 808 nm and 1/e² width of 2 nm. The spectral range in this example is from approximately 806.4 nm to 809.6 nm. In some applications, it may be desirable to have a wider or narrower spectral output. The mere addition of emitters or stacking of diode bars does not provide such spectral shaping capability.

A laser locked diode, such as may be provided by the PowerLocker™ product from Ondax, (assignee of the present application) may also be used. In the laser locked implementation, each diode of the array is locked to the same wavelength. This solution can provide a desired narrow spectral distribution, but a wider spectral distribution may be desired.

### BRIEF SUMMARY OF THE INVENTION

The present invention provides controlling the locked wavelength of individual diodes in an array such that the spectral output of the array when taken as a whole is of the desired form for a given application. In one embodiment, a volume holographic grating is formed that has a wavelength that varies on the filter in accordance with the physical position of a laser emitter in a diode bar or stack. The system can be used in connection with a collimator disposed to receive the output of a diode bar or stack of diode bars. The modified filter is then disposed adjacent the output of the collimator to provide a suitable shaped spectral output. This technique can be applied to stacks of laser diode bars, where each bar can be made to operate at any desired wavelength, or even individual emitters within the bar, such that the combined spectral output is designed for a particular application.

### BRIEF DESCRIPTION OF THE DRAWINGS

FIG. 1A is an example of an un-stabilized diode bar.

FIG. 1B is an example of a stabilized diode bar.

FIG. 2A is an example of an un-stabilized diode bar stack.

FIG. 2B is an example of a stabilized diode bar stack.

FIG. 3 is an example of the spectral output of a laser.

FIG. 4 is a schematic representation of a holographic filter writing system.

FIG. 5A is an example of two possible wavelength distributions on a filter to provide a widening spectral output.

FIG. 5B illustrates the spectral output of the filter of FIG. 5A.

FIG. 6A illustrates the wavelength distribution on a filter to provide a dual peak spectral output.

FIG. 6B illustrates the spectral output of the filter of FIG. 6A.

FIG. 7A illustrates the wavelength distribution on a filter to provide a flat-top spectral output.

FIG. 7B illustrates the spectral output of the filter of FIG. 7A.

### DETAILED DESCRIPTION OF THE PREFERRED EMBODIMENTS

The present system provides spectral control of laser diode bars and stacks. The embodiments of the improved system and method are illustrated and described herein by way of example only and not by way of limitation.

It may be desired to provide laser output whose spectral shape has certain characteristics. However, the native spectral shape of the laser output may not be ideal, or the width needs to be modified in a controlled fashion. In one embodiment of the invention, spectral control is accomplished by using a volume holographic grating that has a center wavelength that is not uniform across the length of the bar. Instead, the wavelength profile on the grating is tailored to meet the needs of the application. When combined with a laser diode bar, each individual laser diode operates at a wavelength determined by that portion of the volume holographic grating to which it is adjacent. In this way, the center wavelength of each laser diode is controlled such that the combined spectrum when the entire bar is fiber-coupled produces a desired spectral shape. Similarly, this technique can be applied to stacks of laser diode bars, where each bar can be made to operate at any desired wavelength, or even individual emitters within the bar, such that the combined spectral output is designed for a particular application.

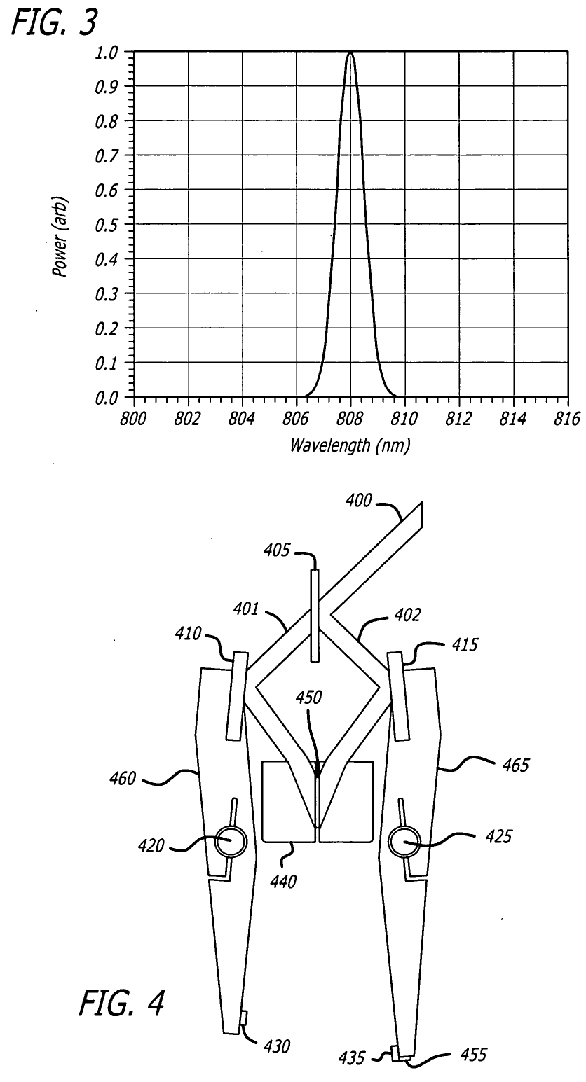

For purposes of example, the present invention proposes a diode bar having 6 emitters operating at a nominal wavelength of 808 nm with the individual spectral shape as shown in FIG. 3. The examples here are for illustration only, and are not intended to constrain the range of applicability of this invention to the general technique of spectral control or to constrain the technique to any particular wavelength or spectral width.

Widening Spectral Shape

In each case below a plot of the filter's wavelength distribution is provided followed by the combined spectral output of 6 lasers that individually have a spectral shape as shown in FIG. 3 and are locked with a filter with the corresponding wavelength distribution.

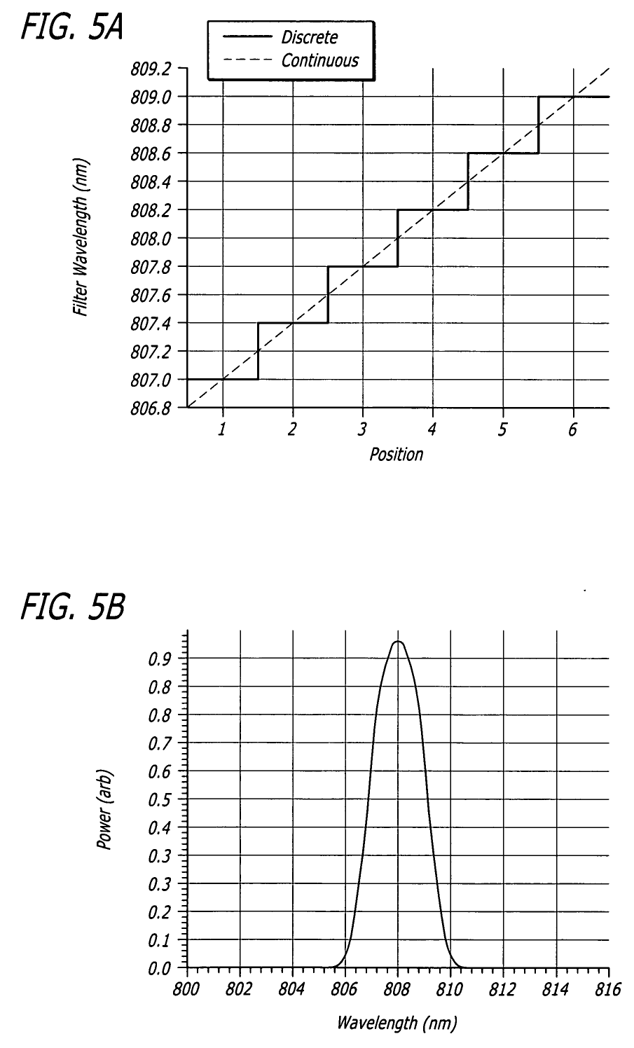

FIG. 5A illustrates two possible wavelength distributions of a filter that varies with emitter position. The vertical axis of FIG. 5A represents the wavelength of the holographic filter and the horizontal axis represents the position of an emitter on the diode bar. The dashed line 401 represents a linear variation of the filter and the solid line 402 represents a stepwise variation of the filter. Regardless of the type of variation of the filter with distance, the regions adjacent to the emitters on the diode bar are configured so that an appropriate wavelength is provided. For example, at the first emitter position, both the linear variation model 401 and the stepwise variation model 402 results in a filter wavelength of approximately 807 nm. At the sixth position, the filter wavelength is approximately 809 nm.

It should be noted that the variation may be non-linear as well (e.g. a quadratic or some other non-linear function).

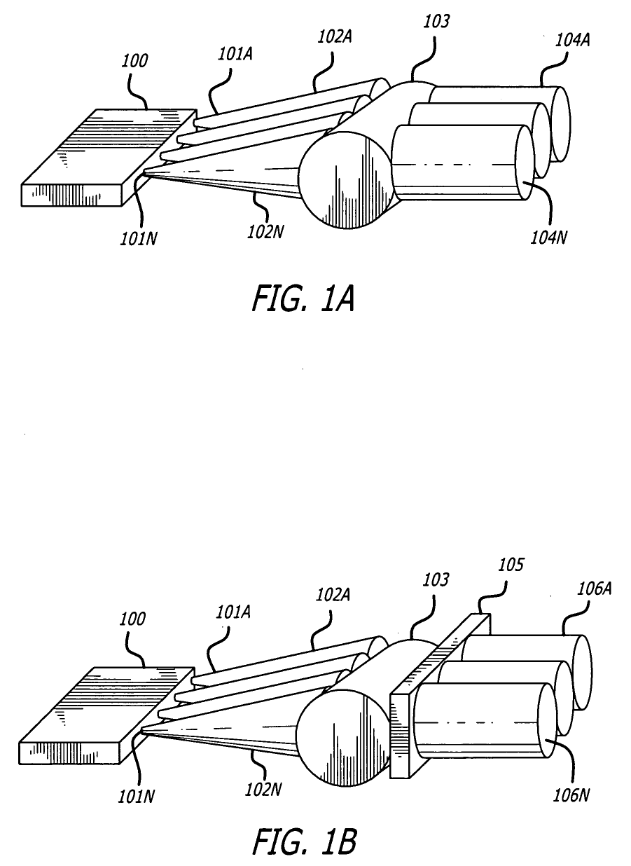

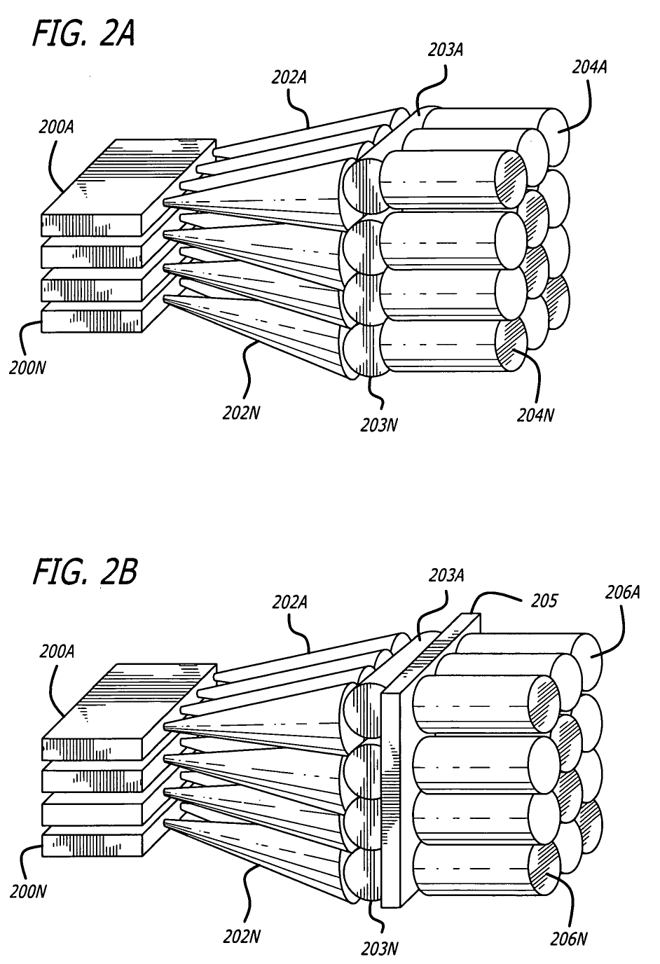

FIG. 5B illustrates the spectral output of an example diode bar when either filter of FIG. 5A is applied in the manner shown in FIGS. 1B or 2B. The spectral shape is still centered on 808 nm but has a wider range than the example of FIG. 3. In this example of FIG. 5A, the range is from 805.6 nm to 810.4 nm. It should be noted that the invention in all instances may be practiced with or without a collimator as desired without departing from the scope or spirit of the invention. In addition, the output wavelength may be adjusted by altering the position of the volume holographic grating relative to the bar.

Double Peak Example

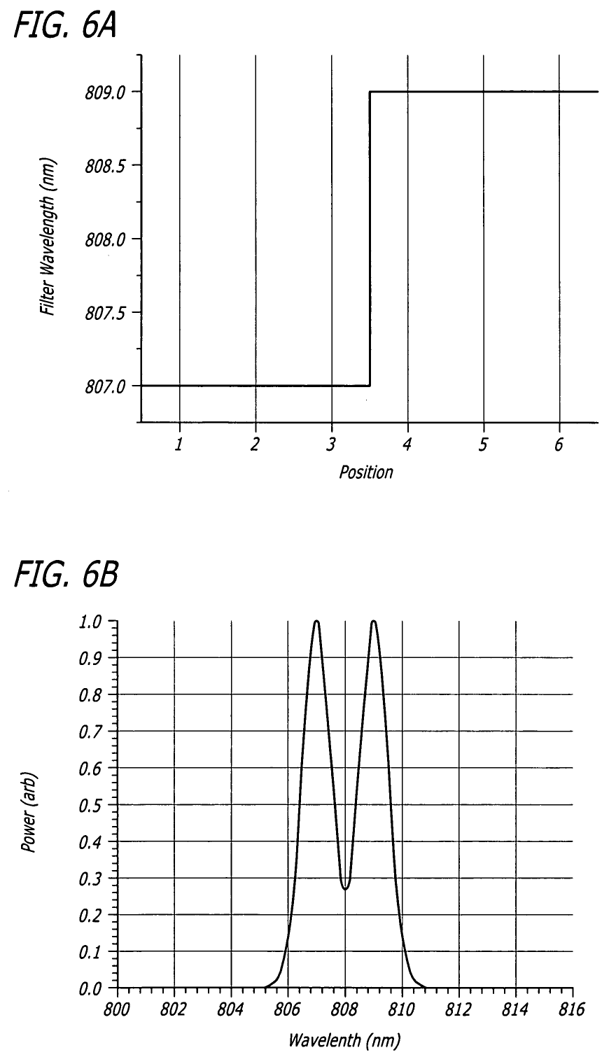

The invention can also be used to result in a spectral shape with a double peak as desired. FIG. 6A illustrates a filter with a stepped wavelength variation represented by line 501 that is low for the first three diode positions (e.g. approximately 807 nm) and higher for the last three diode positions (e.g. approximately 809 nm). The spectral output with this filter appears as in FIG. 6B as a double peak output with peaks centered about 807 and 809 nm respectively. Note that the width of the spectral shape is approximately the same as in FIG. 5B, but the overall shape is different.

Flat-Top Example

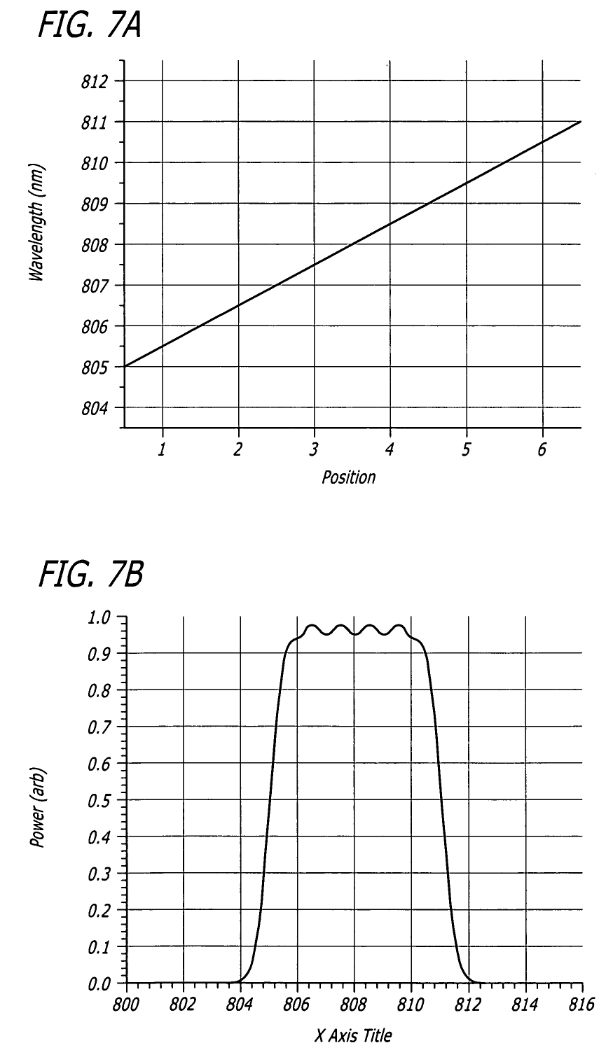

The invention may also be implemented so as to provide a relatively flat topped spectral shape output. The filter variation is illustrated in FIG. 7A as a linear variation 601 from approximately 805 nm at diode position one to approximately 810 nm at diode position six. The resulting spectral output appears as in FIG. 7B as a relatively flat-topped shape centered about 808 nm but with a wide range of approximately 803.6 nm to 812.4 nm.

It will be apparent that any number of filter variations may be implemented to provide the desired spectral shape output as desired.

FIG. 4 is a schematic representation of a volume hologram writing apparatus that can be reconfigured to write more than one grating spacing and slant angle either in a single piece of material, or in different pieces of material and that can be used to create filters used in the present invention. The single fixed input beam 400 is split by beamsplitter 405 into the two writing beam 401 and 402. Writing beam 401 is reflected by mirror 410 towards recording material 450 after passing through transparent block 440. Writing beam 402 is reflected by mirror 415 towards recording material 450 after passing through transparent block 445. Index matching fluid (not shown) is present between the holographic material and transparent blocks as shown in FIG. 3. The angle of each mirror is individually controlled so as to enable individual control of the angle of each writing beam. This enables different grating spacings and tilt angles to be written with a single apparatus. Mirror 410 is on an arm 460 with pivot point 420 and is rotated by use of a linear actuator pushing on the arm at position 430. Mirror 415 is on an arm 465 with pivot point 425 and is rotated by use of a linear actuator pushing on the arm at position 435. By using a linear actuator positioned a distance away from the pivot point, high angular accuracy and repeatability can be achieved with a low cost linear actuator. Counterbalance weight 455 is used to balance the rotating arms and dampen vibration. The positioning of the mirrors 410 and 415 relative to their respective pivot points 420 and 425 is chosen to minimize the translation of the point of intersection of the two writing beams 401 and 402 at the point of holographic material 450. As a result the holographic material can remain in a fixed position. The location of the mirrors is chosen with the assistance of solids modeling and ray tracing software.

The apparatus of FIG. 4 enables writing of a consistent grating throughout a large piece of holographic material that can then be diced into smaller pieces according to the requirements of the final application of the volume holographic grating. Since the final pieces are read-out through the same optical surfaces through which the grating was recorded, further polishing is not required thereby reducing cost and processing time over the prior-art method as described in U.S. Pat. No. 5,491,570.

In an alternative embodiment, one of the mirrors is mounted on a linear actuator, which can be a piezo-electric transducer, and dithered back and forth at a frequency ω during writing. This allows the fringe visibility of the interfering writing beams to be precisely controlled, depending on the modulation amplitude, without having to change the relative intensity of the writing beams. The resultant hologram's modulation depth can therefore be varied while keeping the overall exposure energy constant, which can be advantageous with some holographic materials. As an extension, phase locking can be accomplished by keeping the dithering amplitude small and monitoring the interference between the dithered writing beam and the fixed writing beam, where appropriate reflection is used to deflect both beams into a common path after passing through the holographic material. This can be accomplished by placing a beamsplitter above the holographic material and using oversized writing beams, or by utilizing the partial reflection occurring due to a slight refractive index mismatch between the transparent blocks and index matching fluid, or between the index matching fluid and refractive index of the holographic material. The interference of the beams is detected by a suitable photodetector, and the resultant electrical signal passed to a lock-in amplifier and control system that acts to minimize the ω signal or maximize the 2ω signal by varying the DC offset position of the linear actuator.

In another alternative embodiment, one of the mirrors is replaced with a coherent reflecting beamsplitter to generate a multitude of writing beams thereby causing multiple holographic gratings to be recorded simultaneously.

In another alternative embodiment, a phase mask, amplitude mask, or both, can be placed into one or both of the writing beams in order to record complex phase and/or amplitude patterns.

In another alternative embodiment, a horizontal slit is placed in the path of the input beam 400 before the beamsplitter 405. During the writing process the slit is moved vertically, out of the plane of the diagram, so as to modify the exposure energy as a function of position on the holographic material. This is used to cause arbitrarily selectable spatially varying diffraction efficiencies to be written along one dimension of the holographic material.

In another alternative embodiment, the holographic material is exposed with white light to counter the effects of ultraviolet light induced absorption exhibited by some types of holographic materials when written with ultraviolet light.

In another alternative embodiment, the holographic material is exposed with light to which it is photosensitive so as to decrease the fringe visibility of the writing beams and decrease the resultant hologram diffraction efficiency while keeping the overall exposure energy constant.

Thus, spectral control of laser diodes and stacks has been described.

What is claimed is:

1. A system for providing a desired spectral output comprising:
a diode bar having a plurality of emitters, the emitters providing a first plurality of output beams;
a variable wavelength volume holographic filter disposed adjacent the collimator and modifying the second plurality of output beams to a third plurality of output beams having the desired spectral output.

2. The system of claim 1 wherein the holographic filter has a variable wavelength corresponding to the relative positions of the plurality of emitters.

3. The system of claim 2 wherein the wavelength varies linearly.

4. The system of claim 2 wherein the wavelength varies non-linearly.

5. The system of claim 1 wherein the wavelength varies in a stepped manner.

6. The system of claim 1 further including a stack comprising a plurality of diode bars.

7. The system of claim 1 where the wavelength of the third plurality of output beams may be altered by movement of the filter relative to the diode bar.
